(19) United States
(12) Patent Application Publication
(10) Pub. No.: US 2025/0253140 A1
(43) Pub. Date: Aug. 7, 2025

(54) GAS PROCESSING APPARATUS

(71) Applicant: SAMSUNG ELECTRONICS CO.,LTD., Suwon-si (KR)

(72) Inventors: Hyun Seok KIM, Suwon-si (KR); BongJu LEE, Pohang-si (KR); DZEYEWIRDIVINE NvuyKi, Pohang-si (KR); Mukyeong KIM, Suwon-si (KR); DAJEONG LIM, Suwon-si (KR); SEJIN PARK, Suwon-si (KR); Hyunmin JEONG, Suwon-si (KR); Iljeong HEO, Suwon-si (KR)

(73) Assignees: SAMSUNG ELECTRONICS CO.,LTD., Suwon-si (KR); HANDONG GLOBAL UNIVERSITY INDUSTRY-ACADEMIC COOPERATION FOUNDATION, Pohang-si (KR)

(21) Appl. No.: 19/044,174

(22) Filed: Feb. 3, 2025

(30) Foreign Application Priority Data
Feb. 6, 2024 (KR) 10-2024-0018362
May 28, 2024 (KR) 10-2024-0069331

(51) Int. Cl. H01J 37/32

(52) U.S. Cl. CPC H01J 37/32844; H01J 37/32128; H01J 37/3244; H01J 37/32541; H01J 37/32568

(57) ABSTRACT

A gas processing apparatus includes a gas processing component including a process fluid path through which gas flows; and an excitation power member connected to the gas processing component and configured to provide electric power for plasma excitation, where the gas processing component includes: (i) a ground electrode that is exposed to an interior wall of the process fluid path, and (ii) an excitation electrode on an inner side of the process fluid path and spaced apart from the ground electrode, where the excitation power member is electrically connected to the excitation electrode.

### CROSS-REFERENCE TO RELATED APPLICATION

This application claims priority to and the benefit of Korean Patent Application No. 10-2024-0018362 filed in the Korean Intellectual Property Office on Feb. 6, 2024, and Korean Patent Application No. 10-2024-0069331 filed in the Korean Intellectual Property Office on May 28, 2024, the entire contents of which are incorporated herein by reference.

### BACKGROUND

### 1. Field

The present disclosure relates to a gas processing apparatus capable of processing gas discharged from production facilities.

### 2. Description of the Related Art

Production facilities may discharge gas during a manufacturing process. For example, a semiconductor device may be manufactured by a semiconductor production facility. The semiconductor device may be manufactured through photo process, etching process, deposition process, or the like, on wafers made of, for example, silicon. A variety of chemicals can be used in these processes. Accordingly, chemicals used in the processes, or substances generated during the processes may be included in the gas discharged from semiconductor production facilities performing such processes. These substances may cause environmental pollution, and require treatment before being released into the atmosphere.

### SUMMARY

The present disclosure attempts to provide a gas processing apparatus capable of processing gas discharged from production facilities by an environment-friendly method.

However, the objective of the present disclosure is not limited to the aforementioned one, and may be extended in various ways within the spirit and scope of the present disclosure.

According to an aspect of the disclosure, a gas processing apparatus includes a gas processing component including a process fluid path through which gas flows; and an excitation power member connected to the gas processing component and configured to provide electric power for plasma excitation, where the gas processing component includes (i) a ground electrode that is exposed to an interior wall of the process fluid path, and (ii) an excitation electrode on an inner side of the process fluid path and spaced apart from the ground electrode, where the excitation power member is electrically connected to the excitation electrode.

According to an aspect of the disclosure, a gas processing apparatus, including: a first gas processing component including (i) a ground electrode that is exposed to an interior wall of a process fluid path through which gas flows, and (ii) an excitation electrode on an inner side of the process fluid path; an first excitation power member connected to the first gas processing component and configured to provide electric power for plasma excitation; a second gas processing component coupled in series with the first gas processing component, the second gas processing component including (i) a ground electrode that is exposed to an interior wall of a process fluid path through which gas flows, and (ii) an excitation electrode on an inner side of the process fluid path; a second excitation power member connected to the second gas processing component and configured to provide electric power for plasma excitation; and a steam supply member configured to supply aqueous vapor to one of the first gas processing component and the second gas processing component.

According to an aspect of the disclosure, a gas processing apparatus, including: a first gas processing component including (i) a ground electrode that is exposed to an interior wall of a process fluid path through which gas flows, and (ii) an excitation electrode disposed on an inner side of the process fluid path; an first excitation power member connected to the first gas processing component and configured to provide electric power for plasma excitation; a steam supply member configured to supply aqueous vapor to the first gas processing component; a second gas processing component coupled in series with the first gas processing component, the second gas processing component including (i) a ground electrode that is exposed to an interior wall of a process fluid path through which gas flows, and (ii) an excitation electrode disposed on an inner side of the process fluid path; a second excitation power member connected to the second gas processing component and configured to provide electric power for plasma excitation, wherein the electric power supplied by the second excitation power member is greater than the electric power supplied by the first excitation power member.

According to one or more embodiments, a gas processing apparatus capable of processing gas discharged from production facilities by an environment-friendly method may be provided.

### BRIEF DESCRIPTION OF DRAWINGS

FIG. 1 is a drawing showing a gas processing apparatus according to one or more embodiments.

FIG. 2 is a drawing showing the gas processing module of FIG. 1.

FIG. 3 is a cross-sectional view taken along a direction perpendicular to a length direction of the gas processing module of FIG. 2.

FIG. 4 is a drawing showing a waveform of a voltage applied by excitation power member according to one or more embodiments.

FIG. 5 is a drawing showing a waveform of a voltage applied by an excitation power member according to one or more embodiments.

FIG. 6 is a drawing showing a waveform of a voltage applied by an excitation power member according to one or more embodiments.

FIG. 7 is a drawing showing a waveform of a voltage applied by an excitation power member according to one or more embodiments.

FIG. 8 is a cross-sectional view of a gas processing module according to one or more embodiments, taken along a direction perpendicular to a length direction.

FIG. 9 is a cross-sectional view of a gas processing module according to one or more embodiments, taken along a direction perpendicular to a length direction.

FIG. 10 is a cross-sectional view of a gas processing module according to one or more embodiments, taken along a direction perpendicular to a length direction.

FIG. 11 is a cross-sectional view of a gas processing module according to one or more embodiments, taken along a direction perpendicular to a length direction.

FIG. 12 is a cross-sectional view of a gas processing module according to one or more embodiments, taken along a length direction.

FIG. 13 is a drawing showing a first end of a gas processing module according to one or more embodiments viewed along length direction.

FIG. 14 is a drawing showing a gas processing apparatus according to one or more embodiments.

FIG. 15 is a drawing showing a gas processing apparatus according to one or more embodiments.

FIG. 16 is a cross-sectional view of a region in which a steam supply member is connected to a process fluid path.

FIG. 17 is a drawing showing a gas processing apparatus according to one or more embodiments.

FIG. 18 is a drawing showing a gas processing apparatus according to one or more embodiments.

FIG. 19 is a drawing showing a gas processing apparatus according to one or more embodiments.

### DETAILED DESCRIPTION OF EMBODIMENTS

The present disclosure will be described more fully hereinafter with reference to the accompanying drawings, in which embodiments of the disclosure are shown. As those skilled in the art would realize, the described embodiments may be modified in various different ways, all without departing from the spirit or scope of the present disclosure.

In order to clearly describe the present invention, parts or portions that are irrelevant to the description are omitted, and identical or similar constituent elements throughout the specification are denoted by the same reference numerals.

Further, in the drawings, the size and thickness of each element are arbitrarily illustrated for ease of description, and the present disclosure is not necessarily limited to those illustrated in the drawings. In the drawings, the thicknesses of layers, films, panels, regions, areas, etc., are exaggerated for clarity. In the drawings, for ease of description, the thicknesses of some layers and areas are exaggerated.

It will be understood that when an element such as a layer, film, region, area, or substrate is referred to as being “on” or “above” another element, it can be directly on the other element or intervening elements may also be present. In contrast, when an element is referred to as being “directly on” another element, there are no intervening elements present. Further, in the specification, the word “on” or “above” means disposed on or below the object portion, and does not necessarily mean disposed on the upper side of the object portion based on a gravitational direction.

In one or more examples, unless explicitly described to the contrary, the word “comprise” and variations such as “comprises” or “comprising” will be understood to imply the inclusion of stated elements but not the exclusion of any other elements.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

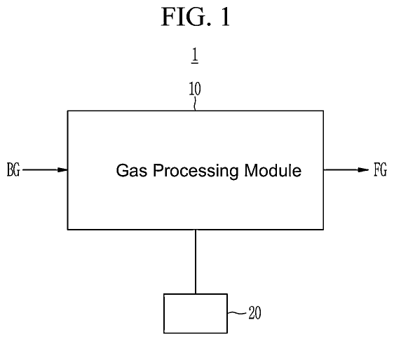

FIG. 1 is a drawing showing a gas processing apparatus 1 according to one or more embodiments.

Referring to FIG. 1, the gas processing apparatus 1, according to one or more embodiments, may include a gas processing module 10 and an excitation power member 20. The gas processing module 10 may be referred to as a gas processing component.

Upon receiving an unprocessed gas BG through a first end of the gas processing module 10, the gas processing apparatus 1 may process the unprocessed gas BG, and then discharge a processed gas FG through a second end of the gas processing module 10. The direction that the first end of the gas processing apparatus 1 faces is the direction in which the gas is introduced and may be referred to as an upstream direction, and the direction that the second end of the gas processing apparatus 1 faces is the direction in which the gas is discharged and may be referred to as an downstream direction.

The unprocessed gas BG may be gas discharged from production facilities. For example, production facilities may be semiconductor production facilities, or the like. The unprocessed gas BG introduced into the gas processing apparatus 1 may be gas discharged from the semiconductor production facilities, or gas obtained by primarily processing the gas discharged from the semiconductor production facilities.

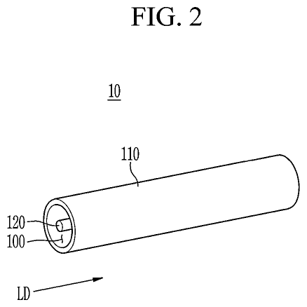

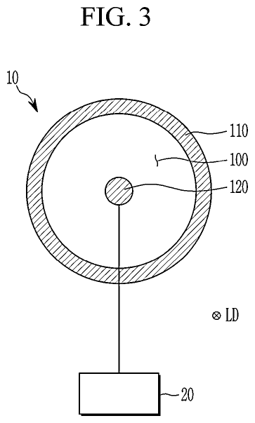

FIG. 2 is a drawing showing the gas processing module 10 of FIG. 1, according to one or more embodiments. FIG. 3 is a cross-sectional view taken along a direction perpendicular to a length direction LD of the gas processing module 10 of FIG. 2, according to one or more embodiments.

Referring to FIG. 2 and FIG. 3, the gas processing module 10 may include a process fluid path 100 through which gas flows, a ground electrode 110 and an excitation electrode 120. Hereinafter, a direction directed from a first end to a second end of the process fluid path 100 may be referred to as the length direction LD of the process fluid path 100. For example, the direction of the arrow for the length direction LD points from the upstream direction to the downstream direction. FIG. 2 shows an example that the length direction LD of the process fluid path 100 is a straight line, but the structure of the process fluid path 100 is not limited thereto. That is, except that the length direction LD of the process fluid path 100 is a straight line, it may be in a curved line shape, a shape bent at at least one point, or the like.

The process fluid path 100 configured to flow gas may have a predetermined length along the length direction LD. A cross-section of the process fluid path 100, according to a direction perpendicular to the length direction LD, may have a predetermined area. The area of the process fluid path 100 according to the direction perpendicular to the length direction LD may be the same along the length direction LD. In one or more examples, the area of the process fluid path 100, according to the direction perpendicular to the length direction LD, may be different region by region along the length direction LD. For example, the cross-sectional shape of the process fluid path 100 according to the direction perpendicular to the length direction LD may be circular, or the like. In one or more examples, the shape of the gas processing module 10 may vary along the length LD. For example, the diameter of the gas processing module 10 may be reduced in one or more regions along the length LD to speed up the flow of gas as necessary. The unprocessed gas BG may be introduced to the first end of the process fluid path 100. The gas may flow through the process fluid path 100, and then may be discharged through the second end of the process fluid path 100 as the processed gas FG.

The ground electrode 110 may be exposed to an interior wall of the process fluid path 100. The ground electrode 110 may be provided as a conductive material. For example, the ground electrode 110 may be provided as a metallic material, or the like. For example, the ground electrode 110 may be made of copper, zinc, galvanized steel, or any other suitable material known to one of ordinary skill in the art. The ground electrode 110 may be grounded. The ground electrode 110 may be disposed along the length direction LD of the process fluid path 100. Accordingly, the ground electrode 110 may be disposed over the entire region along the length direction LD of the process fluid path 100. For example, the ground electrode 110 may be provided in a pipe structure, such that the process fluid path 100 may be located inside ground electrode 110. As understood by one of ordinary skill in the art, the pipe structure enables the flow of gas from the upstream direction to the downstream direction along the length LD.

The excitation electrode 120 may be disposed on an inner side of the process fluid path 100. The excitation electrode 120 may be spaced apart from the ground electrode 110. The excitation electrode 120 may have a rod structure, and may be disposed toward the length direction LD of the process fluid path 100. For example, the excitation electrode 120 may have a length corresponding to a length of the process fluid path 100, and may be disposed along the length direction LD of the process fluid path 100. The excitation electrode 120 may be disposed in a central region of the process fluid path 100. For example, the excitation electrode 120 may have a length that is shorter than the length of the ground electrode 110, where the excitation electrode 120 may be disposed in a central region of the process fluid path. In one or more examples, the excitation electrode 120 may be disposed closer to the first end of the gas processing module 10 (e.g., upstream end) or closer to the second end of the gas processing module 10 (e.g., downstream end). In one or more examples, the excitation electrode 120 may be fixed by a support member of an insulation material at at least one point.

The excitation power member 20 may be connected to the gas processing module 10, such that electric power for excitation of plasma may be provided to the inner side of the process fluid path 100. The excitation power member 20 may be electrically connected to the excitation electrode 120.

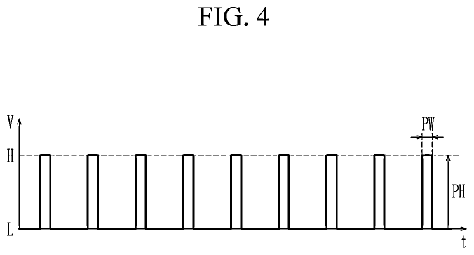

FIG. 4 is a drawing showing a waveform of a voltage applied by the excitation power member 20 according to one or more embodiments.

Referring to FIG. 4, the excitation power member 20 may apply a voltage of having a pulse waveform to the excitation electrode 120. In one or more examples, the voltage applied by the excitation power member 20 may vary between a low value L and a high value H. For example, the excitation power member 20 may include a DC voltage source and a switch. In one or more examples, a voltage of a pulse waveform may be applied to the excitation electrode 120 according to the on/off change of the switch. At this time, the switch may be a power semiconductor device. For example, the switch may be an insulated-gate bipolar transistor (IGBT), a power MOSFET, or the like. In one or more examples, an on/off state of the power semiconductor device may be controlled by a gate driver, which may be a power amplifier that generates a high-current drive input for a high-power transistor's gate. For example, the gate driver may be a power amplifier that accepts a low-power input from a controller and produces a high-current drive input for the gate of a high-power transistor such as an IGBT or power MOSFET. Accordingly, when the high-current drive is output from the gate driver, the excitation electrode 120 may produce a voltage corresponding to a logic high, and when the high-current drive is not output from the gate driver, the excitation electrode 120 may produce a voltage corresponding to a logic low. The width of a pulse may correspond to an amount of time that the gate driver outputs the high-current drive.

The voltage applied by the excitation power member 20 may have a predetermined frequency. For example, the frequency of the voltage applied by the excitation power member 20 may be 100 Hz to 10 kHz. The voltage applied by the excitation power member 20 may have a pulse width PW below a predetermined value. For example, the pulse width PW may be greater than 0 μsec and smaller than or equal to 100 μsec. In one or more examples, such that the voltage applied by the excitation power member 20 may have a pulse waveform, the pulse width PW may be adjusted to correspond to the frequency. A pulse of the voltage applied by the excitation power member 20 may have a predetermined height PH. The height PH of the pulse may be greater than or equal to 10 kV. The low value L of the voltage applied by the excitation power member 20 may be 0V, and the high value H may be greater than or equal to 10 kV.

Plasma may be generated through corona discharge between the excitation electrode 120 and the ground electrode 110 by the voltage applied by the excitation power member 20. The plasma may remove a substance included in the unprocessed gas BG. In one or more example, the substance to be removed may be nitrogen oxide (NOₓ). The plasma may induce a chemical reaction that changes the nitrogen oxide to nitric acid (HNO₃). Accordingly, the processed gas FG discharged from the gas processing apparatus 1 may include the nitric acid originating from the nitrogen oxide. In one or more examples, the removal of a substance may refer to a complete removal of the substance, or a substantial removal of the substance such that trace amounts of the substance remain in the processed gas FG. For example, the substantial removal of the substance may refer to removing the substance such that the percentage of the substance in the processed gas FG is no more than 10% of the volume of the processed gas.

In more detail, nitrogen monoxide (NO) included in the unprocessed gas BG may be changed to nitrogen dioxide (NO₂) by one of reactions of Chemical Formula 1, Chemical Formula 2, and Chemical Formula 3 shown below. At this time, the reactants that reacts with nitrogen monoxide may originate from the unprocessed gas BG, or may be generated as the substance included in the unprocessed gas BG reacts with plasma.

NO+O→NO₂ [Chemical Formula 1]

NO+HO₂→NO₂+OH [Chemical Formula 2]

NO+O₃→NO₂+O₂ [Chemical Formula 3]

In one or more examples, the nitrogen monoxide (NO) included in the unprocessed gas BG may be changed to nitrogen dioxide (NO₂) by Chemical Formula 4 and Chemical Formula 5 shown below. At this time, a hydroxyl group (OH) that reacts with nitrogen monoxide and nitrous acid (HNO₂) may originate from the unprocessed gas BG, or may be generated as the substance included in the unprocessed gas BG reacts with plasma.

NO+OH→HNO₂ [Chemical Formula 4]

HNO₂+OH→NO₂+H₂O [Chemical Formula 5]

In one or more examples, the nitrogen dioxide generated as the nitrogen dioxide included in the unprocessed gas BG or the nitrogen monoxide included in the unprocessed gas BG chemically react with each other may be changed to the nitric acid by reaction of Chemical Formula 6 shown below. At this time, the hydroxyl group that reacts with nitrogen dioxide may originate from the unprocessed gas BG, or may be generated as the substance included in the unprocessed gas BG reacts with plasma.

NO₂+OH→HNO₃ [Chemical Formula 6]

As understood by one of ordinary skill in the art, nitric acid has the property of being highly soluble in water. Accordingly, when wet processing the processed gas FG, the nitric acid may be removed from the processed gas FG.

The gas processing apparatus 1, according to one or more embodiments, may change the substance to be removed included in the unprocessed gas BG to a state removable through wet processing by only using the electrical energy. At this time, the substance generating nitric acid by reacting with nitrogen dioxide may directly react with nitrogen dioxide. In one or more examples, the reaction in which nitrogen monoxide passes through nitrous acid to produce nitric acid also requires a short reaction step. In one or more examples, nitrogen monoxide reacts directly with reactants to produce nitrogen dioxide. Accordingly, the process of converting the nitrogen oxide to the nitric acid is performed with high energy efficiency.

In one or more examples, in the gas processing apparatus 1 according to one or more embodiments, high-energy electrons generated through plasma discharge collide to accelerate the chemical reaction that changes the nitrogen oxide to the nitric acid. Accordingly, the process of converting the nitrogen oxide to the nitric acid is performed with high energy efficiency.

In one or more examples, as the excitation power member 20 applies a voltage in the form of pulses, plasma may be excited through low-temperature discharge between the excitation electrode 120 and the ground electrode 110. Accordingly, the gas processing apparatus 1 may be prevented from being excessively heated during usage, thereby improving convenience and safety.

In one or more examples, the process of converting the nitrogen oxide to the nitric acid may be performed through plasma without additional chemicals. In one or more examples, the process of removing the nitric acid from the processed gas FG may be performed with only water treatment without additional chemicals. Accordingly, the gas processing apparatus 1 according to one or more embodiments may environment-friendly process the gas discharged from production facilities.

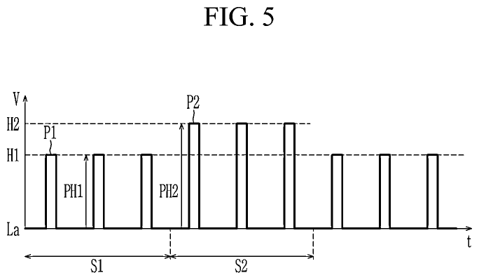

FIG. 5 is a drawing showing the waveform of the voltage applied by the excitation power member 20 according to one or more embodiments.

Referring to FIG. 5, the excitation power member 20 may apply a voltage of pulse waveform to the excitation electrode 120.

The waveform of the voltage applied by the excitation power member 20 may include a first pulse P1 and a second pulse P2 having different heights. Accordingly, the voltage applied by the excitation power member 20 may vary between a low value La and a first high value H1, or between the low value L and a second high value H2. The first pulse P1 may have a first height PH1. The voltage applied by the excitation power member 20 in the first pulse P1 may have the first high value H1. The first height PH1 of the first pulse P1 may be greater than or equal to 10 kV. The low value L of the voltage applied by the excitation power member 20 may be 0V, and first high value H may be greater than or equal to 10 kV.

The second pulse P2 may have a second height PH2. The voltage applied by the excitation power member 20 in the second pulse P2 may have the second high value H2. The second height PH2 of the second pulse P2 is greater than the first height PH1 of the first pulse P1. Accordingly, the second high value H2 is greater than a first high value H1.

The excitation power member 20 may apply a pulse waveform to the excitation electrode 120 in which the first pulse P1 and the second pulse P2 are mixed. For example, the excitation power member 20 may apply the first pulse P1 once or multiple times, and then may apply the second pulse P2 once or multiple times. In one or more examples, the excitation power member 20 may apply the second pulse P2 once or multiple times, and then may apply the first pulse P1 once or multiple times. The waveform of the voltage applied by the excitation power member 20 may include a first section S1 and a second section S2. The first pulse P1 may be applied in the first section S1, and the second pulse P2 may be applied in a second section S2. The number of times by which the first pulse P1 is consecutively applied in each first section S1 may be the same or different. The number of times by which a second pulse P2 is consecutively applied in each second section S2 may be the same or different. The first section S1 may refer to a first time interval, and the second section S2 may refer to a second time interval. In one or more examples, the first section S1 and second section S2 may be the same size. In one or more examples, the first section S1 and the second section S2 may have different sizes. In one or more examples, the first section S1 and the second section S2 may alternate. In one or more examples, the frequency of the first section S1 and the frequency of the second section S2 may vary.

Since the frequency and pulse width of the voltage applied by the excitation power member 20 are the same as or similar to that described above in FIG. 4, the repeated description thereon will not be included herein.

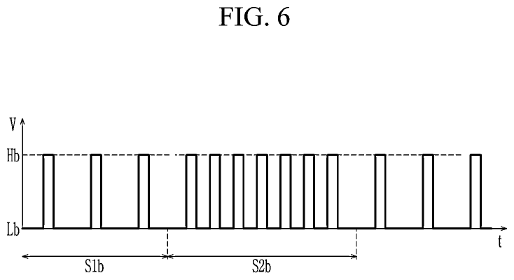

FIG. 6 is a drawing showing the waveform of the voltage applied by the excitation power member 20 according to one or more embodiments.

Referring to FIG. 6, the excitation power member 20 may apply a voltage of having a pulse waveform to the excitation electrode 120. Accordingly, the voltage applied by the excitation power member 20 may vary between a low value Lb and a high value Hb. The waveform of the voltage applied by the excitation power member 20 may have different frequencies section by section. For example, the waveform of the voltage applied by the excitation power member 20 may include a first section S1b and a second section S2b having different frequencies. The voltage applied by the excitation power member 20 in the first section S1b may have a first frequency. The first frequency may be 100 Hz or more. The voltage applied by the excitation power member 20 in the second section S2b may have a second frequency. The second frequency is greater than the first frequency. The second frequency may be 10 kHz or less. The first section S1b may refer to a first time interval, and the second section S2b may refer to a second time interval. In one or more examples, the first section S1b and second section S2b may be the same size. In one or more examples, the first section S1b and the second section S2b may have different sizes. In one or more examples, the first section S1b and the second section S2b may alternate. In one or more examples, the frequency of the first section S1b and the frequency of the second section S2b may vary.

In one or more examples, a height of the pulse of the voltage applied by the excitation power member 20 may be different section by section, the same as or similar to that described above in FIG. 5. That is, the same as or similar to that described above in FIG. 5, heights of the pulse of the first section S1b and the pulse of the second section S2b may be different from each other. In one or more examples, the same as or similar to that described above in FIG. 5, the waveform of the voltage applied by the excitation power member 20 in the first section S1b may include a first pulse and a second pulse having different heights. In one or more examples, the same as or similar to that described above in FIG. 5, the waveform of the voltage applied by the excitation power member 20 in the second section S2b may include a first pulse and a second pulse having different heights.

Since the pulse width of the voltage applied by the excitation power member 20 are the same as or similar to that described above in FIG. 4, the repeated description thereon will not be included herein.

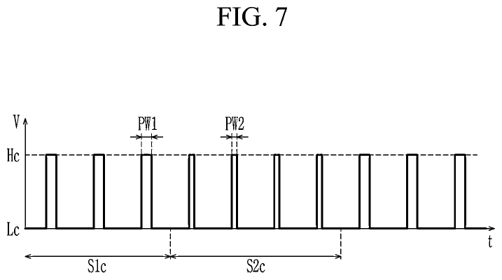

FIG. 7 is a drawing showing the waveform of the voltage applied by the excitation power member 20 according to one or more embodiments.

Referring to FIG. 7, the excitation power member 20 may apply a voltage having a pulse waveform to the excitation electrode 120. Accordingly, the voltage applied by the excitation power member 20 may vary between a low value Lc and a high value Hc. The waveform of the voltage applied by the excitation power member 20 may have pulse widths PW1 and PW2 that are different section by section. For example, the waveform of the voltage applied by the excitation power member 20 may include a first section S1c and a second section S2c having different pulse widths. The pulse applied by the excitation power member 20 in the first section S1c may have a first pulse width PW1. The first pulse width PW1 may be greater than 0 μsec and smaller than or equal to 100 μsec. The pulse applied by the excitation power member 20 in the second section S2c may have a second width PW2. A second pulse width PW2 may exceed 0 μsec, and may be smaller than the first pulse width PW1. The first section S1c may refer to a first time interval, and the second section S2c may refer to a second time interval. In one or more examples, the first section S1c and second section S2c may be the same size. In one or more examples, the first section S1c and the second section S2c may have different sizes. In one or more examples, the first section S1c and the second section S2c may alternate. In one or more examples, the frequency of the first section S1c and the frequency of the second section S2c may vary.

In one or more examples, the height of the pulse of the voltage applied by the excitation power member 20 may be different section by section, the same as or similar to that described above in FIG. 5. That is, the same as or similar to that described above in FIG. 5, heights of the pulse of the first section S1c and the pulse of a second section S1c may be different from each other. In one or more examples, the same as or similar to that described above in FIG. 5, the waveform of the voltage applied by the excitation power member 20 in the first section S1c may include a first pulse and a second pulse having different heights. In one or more examples, the same as or similar to that described above in FIG. 5, the waveform of the voltage applied by the excitation power member 20 in the second section S2c may include a first pulse and a second pulse having different heights.

In one or more examples, the frequency of the voltage applied by the excitation power member 20 may be different section by section, the same as or similar to that described above in FIG. 6. That is, the same as or similar to that described above in FIG. 6, frequencies of the first section S1c and the second section S2c may be different from each other. In one or more examples, the same as or similar to that described above in FIG. 6, the frequency of the voltage applied by the excitation power member 20 in the first section S1c be may have different frequencies depending on subsections included in the first section S1c. In one or more examples, the same as or similar to that described above in FIG. 6, the frequency of the voltage applied by the excitation power member 20 in the second section S2c be may have different frequencies depending on subsections included in the second section S2c.

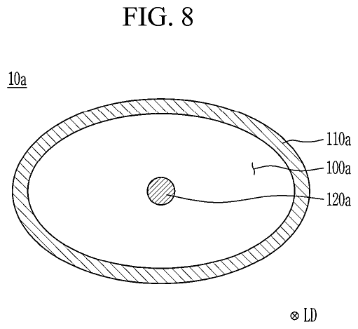

FIG. 8 is a cross-sectional view of the gas processing module 10 according to one or more embodiments, taken along the direction perpendicular to the length direction LD.

Referring to FIG. 8, a gas processing module 10a may include a process fluid path 100a through which gas flows, a ground electrode 110a and an excitation electrode 120a.

The process fluid path 100a, configured to flow gas, may have a predetermined length along the length direction LD. The process fluid path 100a may have predetermined area in cross section according to the direction perpendicular to the length direction LD. The area of the process fluid path 100a according to the direction perpendicular to the length direction LD may be the same along the length direction LD. In one or more examples, the area of the process fluid path 100a according to the direction perpendicular to the length direction LD may be different region by region along the length direction LD. For example, the cross-sectional shape of the process fluid path 100a according to the direction perpendicular to the length direction LD may be an elliptical shape, or the like. In one or more examples, the cross-sectional shape of the process fluid path 100a according to the direction perpendicular to the length direction LD be may be different region by region. For example, the cross-sectional shape of the process fluid path 100a according to the direction perpendicular to the length direction LD may be elliptical in a partial section along the length direction LD, and may be circular in a remaining partial section, as exemplified in FIG. 2 and FIG. 3. In one or more examples, the cross-section shape may be reduced in one or more regions to increase the flow of gas as necessary.

The ground electrode 110a may be exposed to the interior wall of the process fluid path 100a. The ground electrode 110a may be provided as a conductive material. For example, the ground electrode 110a may be provided as a metallic material, or the like. The ground electrode 110a may be grounded. The ground electrode 110a may be disposed along the length direction LD of the process fluid path 100a. Accordingly, the ground electrode 110a may be disposed over the entire region along the length direction LD of the process fluid path 100a. For example, the ground electrode 110a may be provided in a pipe structure, such that the process fluid path 100a may be located inside ground electrode 110a.

The excitation electrode 120a may be disposed on an inner side of the process fluid path 100a. Since the structure of the excitation electrode 120a is the same as or similar to that described above in FIG. 2 and FIG. 3, the repeated description thereon will not be included herein.

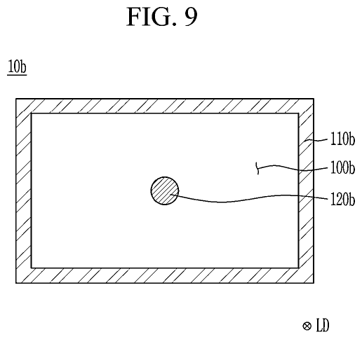

FIG. 9 is a cross-sectional view of a gas processing module 10b along one or more embodiments, taken along the direction perpendicular to the length direction LD.

Referring to FIG. 9, the gas processing module 10b may include a process fluid path 100b through which gas flows, a ground electrode 110b and an excitation electrode 120b.

The process fluid path 100b configured to flow gas may have a predetermined length along the length direction LD. The process fluid path 100b may have predetermined area in cross section according to the direction perpendicular to the length direction LD. The area of the process fluid path 100b according to the direction perpendicular to the length direction LD may be the same along the length direction LD. In one or more examples, the area of the process fluid path 100b according to the direction perpendicular to the length direction LD may be different region by region along the length direction LD. For example, the cross-sectional shape of the process fluid path 100b according to the direction perpendicular to the length direction LD may be a polygon. FIG. 9 shows an example in which the cross-sectional shape of the process fluid path 100b according to a direction perpendicular to the length direction LD is a rectangular shape, which is one of type of polygonal shape that the cross-section may take. In one or more examples, the cross-sectional shape of the process fluid path 100b, according to the direction perpendicular to the length direction LD, may be different region by region. For example, the cross-sectional shape of the process fluid path 100b according to the direction perpendicular to the length direction LD may be one of a polygonal shape, a circular shape exemplified in FIG. 2 and FIG. 3, an elliptical shape exemplified in FIG. 8, in a partial section in the length direction LD, and may be another one of a polygonal shape, the circular shape exemplified in FIG. 2 and FIG. 3, the elliptical shape exemplified in FIG. 8, in a remaining partial section in the length direction LD.

The ground electrode 110b may be exposed to the interior wall of the process fluid path 100b. The ground electrode 110b may be provided as a conductive material. For example, the ground electrode 110b may be provided as a metallic material, or the like. The ground electrode 110b may be grounded. The ground electrode 110b may be disposed along the length direction LD of the process fluid path 100b. Accordingly, the ground electrode 110b may be disposed over the entire region along the length direction LD of the process fluid path 100b. For example, the ground electrode 110b may be provided in a pipe structure, such that the process fluid path 100b may be located inside ground electrode 110b.

The excitation electrode 120b may be disposed on an inner side of the process fluid path 100b. Since the structure of the excitation electrode 120b is the same as or similar to that described above in FIG. 2 and FIG. 3, the repeated description thereon will not be included herein.

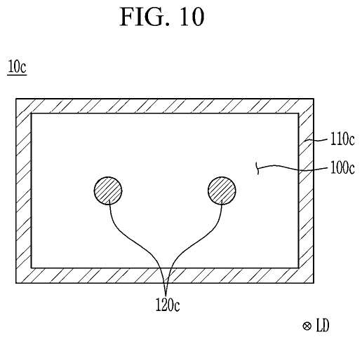

FIG. 10 is a cross-sectional view of a gas processing module 10c along one or more embodiments, taken along the direction perpendicular to the length direction LD.

Referring to FIG. 10, the gas processing module 10c may include a process fluid path 100c through which gas flows, a ground electrode 110c and an excitation electrode 120c.

The process fluid path 100c configured to flow gas may have a predetermined length along the length direction LD. The process fluid path 100c may have predetermined area in cross section according to the direction perpendicular to the length direction LD. The cross-sectional shape of the process fluid path 100c, according to the direction perpendicular to the length direction LD, may be the same as or similar to the shapes described above in FIG. 2 and FIG. 3, FIG. 8, or FIG. 9. FIG. 10 shows an example that the cross-sectional shape of the process fluid path 100c according to a direction perpendicular to the length direction LD is a rectangular shape, which is one of polygonal shapes. In one or more examples, the cross-sectional shape of the process fluid path 100c according to the direction perpendicular to the length direction LD be may be different region by region. For example, the cross-sectional shape of the process fluid path 100c according to the direction perpendicular to the length direction LD may be one of a polygonal shape, a circular shape, and an elliptical shape, in a partial section, and may be another one of a polygonal shape, a circular shape, and an elliptical shape, in a remaining partial section.

The area of the process fluid path 100c, according to the direction perpendicular to the length direction LD, may be the same along the length direction LD. In one or more examples, the area of the process fluid path 100c according to the direction perpendicular to the length direction LD may be different region by region along the length direction LD.

The ground electrode 110c may be exposed to the interior wall of the process fluid path 100c. The ground electrode 110c may be provided as a conductive material. For example, the ground electrode 110c may be provided as a metallic material, or the like. The ground electrode 110c may be grounded. The ground electrode 110c may be disposed along the length direction LD of the process fluid path 100c. Accordingly, the ground electrode 110c may be disposed over the entire region along the length direction LD of the process fluid path 100c. For example, the ground electrode 110c may be provided in a pipe structure, such that the process fluid path 100c may be located inside ground electrode 110c.

The excitation electrode 120c may be disposed on an inner side of the process fluid path 100c. The excitation electrode 120c may be disposed to be spaced apart from the ground electrode 110c. The excitation electrode 120c may have a rod structure, and may be disposed toward the length direction LD of the process fluid path 100c. For example, the excitation electrode 120c may have a length corresponding to the length of the process fluid path 100c, and may be disposed along the length direction LD of the process fluid path 100c. In one or more examples, the excitation electrode 120c may include a plurality of excitation electrodes that are disposed on the inner side of the process fluid path 100c. A plurality of excitation electrodes 120c may be spaced apart from each other. The plurality of excitation electrodes 120c may be electrically connected to the excitation power member 20, respectively. In one or more examples, each of the excitation rods may have the same shape and/or size. In one or more examples, at least one excitation rod from the plurality of excitation rods may be a different shape and/or size from the remaining excitation rods.

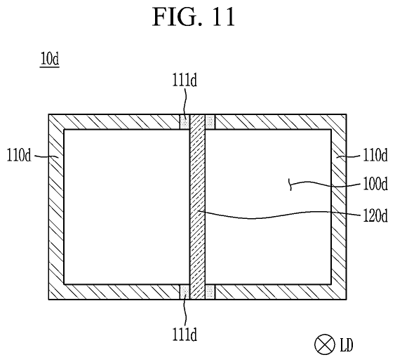

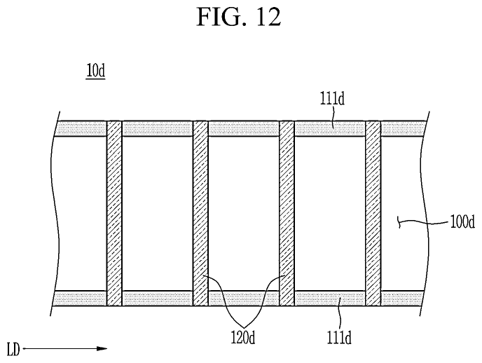

FIG. 11 is a cross-sectional view of a gas processing module 10d along the direction perpendicular to the length direction LD according to one or more embodiments. FIG. 12 is a cross-sectional view of the gas processing module 10d according to one or more embodiments, taken along the length direction LD.

Referring to FIG. 11 and FIG. 12, the gas processing module 10d may include a process fluid path 100d through which gas flows, a ground electrode 110d and an excitation electrode 120d.

The process fluid path 100d configured to flow gas may have a predetermined length along the length direction LD. The process fluid path 100d may have predetermined area in cross section according to the direction perpendicular to the length direction LD. The cross-sectional shape of the process fluid path 100d according to the direction perpendicular to the length direction LD may be the same as or similar to the shapes described above in FIG. 2 and FIG. 3, FIG. 8, or FIG. 9. FIG. 11 shows an example that the cross-sectional shape of the process fluid path 100d according to a direction perpendicular to the length direction LD is a rectangular shape, which is one of polygonal shapes. In one or more examples, the cross-sectional shape of the process fluid path 100d according to the direction perpendicular to the length direction LD be may be different region by region. That is, the cross-sectional shape of the process fluid path 100d according to the direction perpendicular to the length direction LD may be one of a polygonal shape, a circular shape, and an elliptical shape, in a partial section, and may be another one of a polygonal shape, a circular shape, and an elliptical shape, in a remaining partial section.

The area of the process fluid path 100d according to the direction perpendicular to the length direction LD may be the same along the length direction LD. In one or more examples, the area of the process fluid path 100d according to the direction perpendicular to the length direction LD may be different region by region along the length direction LD.

The ground electrode 110d may be exposed to the interior wall of the process fluid path 100d. The ground electrode 110d may be provided as a conductive material. For example, the ground electrode 110d may be provided as a metallic material, or the like. The ground electrode 110d may be grounded. The ground electrode 110d may be disposed along the length direction LD of the process fluid path 100d. Accordingly, the ground electrode 110d may be disposed over the entire region along the length direction LD of the process fluid path 100d.

The excitation electrode 120d may be disposed on an inner side of the process fluid path 100d. The excitation electrode 120d may have a rod structure, and may be disposed inclined with respect to the length direction LD of the process fluid path 100d. Accordingly, one end or both ends of the excitation electrode 120d may be connected to the interior wall of the process fluid path 100d. For example, at least a partial region of the interior wall of the process fluid path 100d may be provided as a support member 111d. The support member 111d may be provided as an insulation material. In one or more examples, at least one side of the excitation electrode 120d may be connected and fixed to the support member 111d. FIG. 11 and FIG. 12 show an example that the support member 111d is disposed on both sides of the process fluid path 100d along a direction crossing the length direction LD, and both sides of the excitation electrode 120d are connected and fixed to the support member 111d. In one or more examples, the excitation electrode 120d may have a rectangular shape that corresponds to the rectangular shape of the ground electrode 110d.

In one or more examples, the processing module 10d may include a plurality of excitation electrodes 120d disposed on the inner side of the process fluid path 100d. The plurality of excitation electrodes 120d may be spaced apart from each other, and disposed along the length direction LD of the process fluid path 100d. The plurality of excitation electrodes 120d may be electrically connected to an excitation power member 20d. In the present embodiment, the plurality of excitation electrodes 120d are described with reference to the region located on the inner side of the process fluid path 100d, and does not merely mean the case that the excitation electrodes 120d are physically separated. For example, each excitation electrode 120d from the plurality of excitation electrodes may be provided in a coil structure, such that they may be connected to each other by a region located outside process fluid path 100d. In one or more examples, each excitation electrodes form the plurality of excitation electrodes may be spaced apart by an equal distance. In one or more examples, at least one excitation electrode from the plurality of excitation electrodes may be spaced apart by a different distance than the remaining excitation electrode. In one or more examples, each excitation electrode from the plurality of excitation electrodes may have a same size and/or shape. In one or more examples, at least one excitation electrode from the plurality of excitation electrodes has a different size and/or shape than the remaining excitation electrodes.

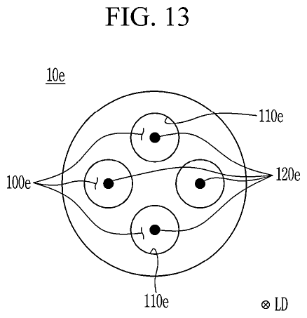

FIG. 13 is a drawing showing a first end of a gas processing module 10e according to one or more embodiments viewed along the length direction LD.

Referring to FIG. 13, the gas processing module 10e may include a process fluid path 100e through which gas flows, a ground electrode 110e and an excitation electrode 120e.

The process fluid path 100e may be provided in a plural quantity. A plurality of process fluid paths 100e may arranged in parallel. Accordingly, the unprocessed gas may be introduced into a first end of each of the plurality of process fluid paths 100e. In one or more examples, the gas may flow through each of the plurality of process fluid paths 100e, and then may be discharged through a second end of the plurality of process fluid paths 100e as the processed gas.

The structure of each of the plurality of process fluid paths 100e may be the same as or similar to one of the process fluid path 100 described above in FIG. 2 and FIG. 3, the process fluid path 100a described above in FIG. 8, and the process fluid path 100b described above in FIG. 9. In one or more examples, the structures of the plurality of process fluid paths 100e may be different from each other. For example, a portion of the plurality of process fluid paths 100e may have a structure that is the same as or similar to a first one of the process fluid path 100 described above in FIG. 2 and FIG. 3, the process fluid path 100a described above in FIG. 8, the process fluid path 100b described above in FIG. 9, and a remaining portion may have a structure that is the same as or similar to a second one of the process fluid path 100 described above in FIG. 2 and FIG. 3, the process fluid path 100a described above in FIG. 8, the process fluid path 100b described above in FIG. 9.

The ground electrode 110e may be disposed on interior walls of the plurality of process fluid paths 100e, respectively. The excitation electrode 120e may be disposed on inner sides of the plurality of process fluid paths 100e, respectively. Corresponding to structures of the plurality of process fluid paths 100e, the structure of the ground electrode 110e and the structure of the excitation electrode 120e may be the same as or similar to the structure described above in FIG. 2 and FIG. 3, the structure described above in FIG. 8, the structure described above in FIG. 9, the structure described above in FIG. 10, the structure described above in FIG. 11 and FIG. 12, and repeated description is not included herein.

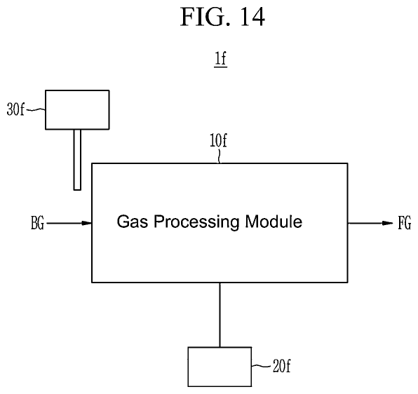

FIG. 14 is a drawing showing a gas processing apparatus 1f according to one or more embodiments.

Referring to FIG. 14, the gas processing apparatus 1f according to one or more embodiments may include a gas processing module 10f, an excitation power member 20f and a steam supply member 30f.

Upon receiving the unprocessed gas BG through a first end, the gas processing apparatus 1f may process the unprocessed gas BG, and then discharge the processed gas FG through a second end.

The steam supply member 30f may supply aqueous vapor to the gas processing module 10f. The steam supply member 30f may be connected to a first end of the gas processing module 10f. Accordingly, the aqueous vapor supplied by the steam supply member 30f may be introduced into the gas processing module 10f together with the unprocessed gas BG. Therefore, the aqueous vapor may be supplied from the upstream position such that the aqueous vapor travels toward the downstream position with the unprocessed gas BG.

The aqueous vapor supplied to the gas processing module 10f may generate a hydroxyl group by reacting with plasma. As a result, the reaction of the Chemical Formula 4, the Chemical Formula 5, and the Chemical Formula 6 described above may be performed more effectively due to the aqueous vapor.

Since the structures of the gas processing module 10f and the excitation power member 20f are the same as or similar to that described above in FIG. 1 to FIG. 13, the repeated description thereon will not be included herein.

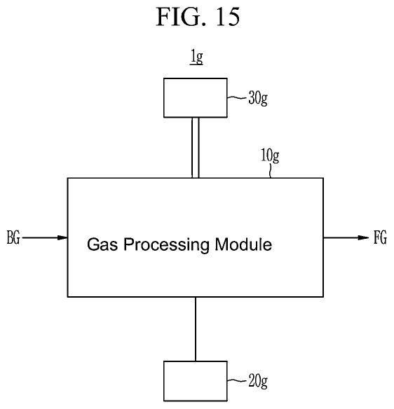

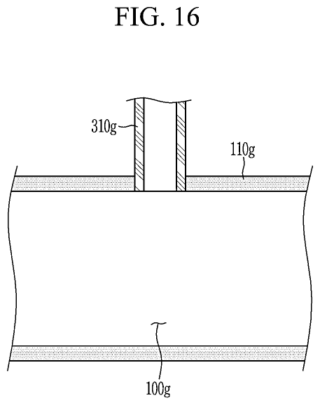

FIG. 15 is a drawing showing a gas processing apparatus 1g according to one or more embodiments. FIG. 16 is a cross-sectional view of a region in which a steam supply member 30g is connected to a process fluid path 100g.

Referring to FIG. 15 and FIG. 16, the gas processing apparatus 1g according to one or more embodiments may include a gas processing module 10g, an excitation power member 20g and the steam supply member 30g.

Upon receiving the unprocessed gas BG through a first end, the gas processing apparatus 1g may process the unprocessed gas BG, and then discharge the processed gas FG through a second end.

The steam supply member 30g may be connected to the process fluid path 100g. Accordingly, the aqueous vapor supplied by the steam supply member 30g may be directly supplied into the process fluid path 100g. The steam supply member 30g may be connected to the process fluid path 100g through a steam supply pipe 310g. The steam supply pipe 310g may electrically insulated from a ground electrode 110g. For example, the steam supply pipe 310g may be provided with an insulation material, or an insulative substance may be located between the steam supply pipe 310g and the ground electrode 110g, such that the steam supply pipe 310g may electrically insulated from the ground electrode 110g. In one or more examples, the steam supply pipe 310g may be connected to the ground electrode 110g at a center portion of the ground electrode 110g. In one or more examples, the steam supply pipe 310g may be connect to the ground electrode 110 at a position closer to the upstream position. In one or more examples, the steam supply pipe 310g may be connected to the ground electrode 110 at a position closer to the downstream position.

Since the structures of the gas processing module 10g and the excitation power member 20g are the same as or similar to that described above in FIG. 1 to FIG. 13, the repeated description thereon will not be included herein.

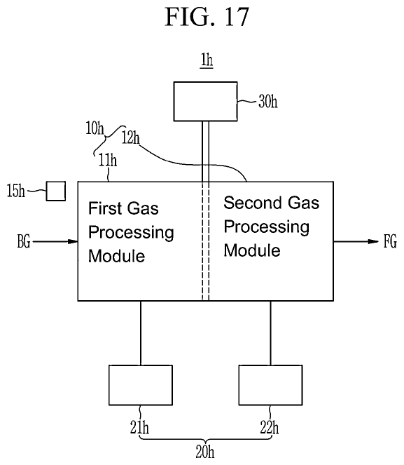

FIG. 17 is a drawing showing a gas processing apparatus 1h according to one or more embodiments.

Referring to FIG. 17, the gas processing apparatus 1h according to one or more embodiments may include a gas processing module 10h, an excitation power member 20h and a steam supply member 30h.

Upon receiving the unprocessed gas BG through a first end, the gas processing apparatus 1h may process the unprocessed gas BG, and then discharge the processed gas FG through a second end.

The gas processing module 10h may include a first gas processing module 11h and a second gas processing module 12h.

The first gas processing module 11h and the second gas processing module 12h may be coupled in series. Accordingly, the unprocessed gas BG may be introduced into a first end of the first gas processing module 11h. In one or more examples, the gas processed inside first gas processing module 11h may be discharged through a second end of the first gas processing module 11h, and then flow into a first end of the second gas processing module 12h. In one or more examples, the gas processed inside second gas processing module 12h may be discharged as the processed gas FG through a second end of the second gas processing module 12h.

Since the structure of the first gas processing module 11h is the same as or similar to that described above in FIG. 1 to FIG. 13, the repeated description thereon will not be included herein. Since the structure of the second gas processing module 12h is the same as or similar to that described above in FIG. 1 to FIG. 13, the repeated description thereon will not be included herein. In one or more examples, the structure of the first gas processing module 11h and the structure of the second gas processing module 12h may be the same or different. That is, as FIG. 1 to FIG. 13 disclose a plurality of embodiments, when the embodiment applied to the first gas processing module 11h is different from the embodiment applied to the second gas processing module 12h, the structure of the first gas processing module 11h and the structure of the second gas processing module 12h may be different. In one or more examples, the number of process fluid paths of the first gas processing module 11h, the number of process fluid paths of the second gas processing module 12h may be the same or different. For example, the first gas processing module 11h and the second gas processing module 12h being coupled in series means that that the gas discharged from the first gas processing module 11h flows into the second gas processing module 12h. Accordingly, it does not necessarily mean that the process fluid path of the first gas processing module 11h and the process fluid path of the second gas processing module 12h are connected in series one by one.

The excitation power member 20h may include a first excitation power member 21h and a second excitation power member 22h.

The first excitation power member 21h may be connected to the first gas processing module 11h. The first excitation power member 21h may have the same or similar structure as the excitation power member 20 described above in FIG. 1 to FIG. 3, and may apply the voltage in the form of the waveform described above in FIG. 4 to FIG. 7.

The second excitation power member 22h may be connected to the second gas processing module 12h. The second excitation power member 22h may have the same or similar structure as the excitation power member 20 described above in FIG. 1 to FIG. 3, and may apply the voltage in the form of the waveform described above in FIG. 4 to FIG. 7.

The magnitudes of the electric power supplied by the first excitation power member 21h and the second excitation power member 22h may be different from each other. The electric power supplied by the second excitation power member 22h may be greater than the electric power supplied by the first excitation power member 21h.

The steam supply member 30h may supply aqueous vapor to the gas processing module 10h.

The steam supply member 30h may connected to a region of the gas processing apparatus 1h in which the first gas processing module 11h and the second gas processing module 12h are connected to each other. The steam supply member 30h may connected between the second end of the first gas processing module 11h and the first end of the second gas processing module 12h. Accordingly, the aqueous vapor supplied by the steam supply member 30h may flow into the first end of the second gas processing module 12h together with the gas discharged through the second end of the first gas processing module 11h.

In the first gas processing module 11h, the reaction of the Chemical Formula 1, the Chemical Formula 2, and the Chemical Formula 3 mentioned above may occur. In one or more examples, in the second gas processing module 12h, the reactions of the Chemical Formula 4, the Chemical Formula 5, and the Chemical Formula 6 described above may occur. To this end, the magnitudes of the electric powers supplied to the first gas processing module 11h and the second gas processing module 12h may be adjusted, individually. In one or more examples, the aqueous vapor may be supplied to the second gas processing module 12h together with the gas discharged from the first gas processing module 11h. Accordingly, by the aqueous vapor, the hydroxyl group required for the chemical reactions of the Chemical Formula 4, the Chemical Formula 5, and the Chemical Formula 6 may be effectively generated. In one or more examples, the amount of the supplied aqueous vapor may be adjusted in order to prevent the plasma energy is consumed by excessively reacting with the aqueous vapor as the amount required for the chemical reactions of the Chemical Formula 4, the Chemical Formula 5, and the Chemical Formula 6 is sufficiently generated. To this end, the amount of the aqueous vapor may be supplied to have a predetermined ratio with respect to the amount of the nitrogen oxide included in the unprocessed gas BG. For example, the aqueous vapor and the nitrogen oxide included in the unprocessed gas BG may have a mole ratio of about 1:1. In consideration of deviation of the amount of the nitrogen oxide included in the unprocessed gas BG, the aqueous vapor and the nitrogen oxide included in the unprocessed gas BG may have a mole ratio of 1:0.9 to 1:1. The amount of the nitrogen oxide may be calculated through concentration of the nitrogen oxide included in the unprocessed gas BG. For example, the unprocessed gas BG may be provided with the concentration of the nitrogen oxide measured in the unit of ppm, such that the amount of the supplied aqueous vapor may be adjusted. To this end, a measurement sensor 15h may be located in the direction along which the unprocessed gas BG is introduced. The measurement sensor 15h may measure concentration of the nitrogen oxide included in the unprocessed gas BG. The measurement sensor 15h may be located on a front side of the gas processing module 10h in the upstream direction. In one or more examples, the measurement sensor 15h may be disposed in an upstream side end portion of the gas processing module 10h. That is, the measurement sensor 15h may be disposed in an upstream side end portion of the first gas processing module 11h. FIG. 17 shows an example that the measurement sensor 15h is located on a front side of the gas processing module 10h in the upstream direction.

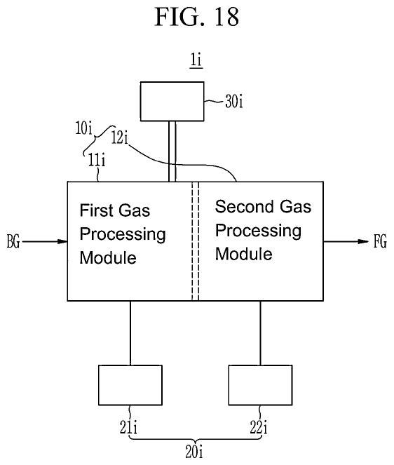

FIG. 18 is a drawing showing a gas processing apparatus 1i according to one or more embodiments.

Referring to FIG. 18, the gas processing apparatus 1i according to one or more embodiments may include a gas processing module 10i, an excitation power member 20i and a steam supply member 30i.

Upon receiving the unprocessed gas BG through a first end, the gas processing apparatus 1i may process the unprocessed gas BG, and then discharge the processed gas FG through a second end.

The gas processing module 10i may include a first gas processing module 11i and a second gas processing module 12i. Since the structure of the gas processing module 10i is the same as or similar to the gas processing module 10h described above in FIG. 17, the repeated description thereon will not be included herein.

The excitation power member 20i may include a first excitation power member 21i and a second excitation power member 22i. Since the structure of the excitation power member 20i is the same as or similar to the excitation power member 20h described above in FIG. 17, the repeated description thereon will not be included herein.

The steam supply member 30i may supply the aqueous vapor to the gas processing module 10i. The steam supply member 30i may be connected to the first gas processing module 11i. The steam supply member 30i may be connected to a second side end portion of the first gas processing module 11i. Here, the second side end portion of the first gas processing module 11i is located in the direction in which the gas is discharged, and may be referred to as a downstream side end portion of the first gas processing module 11i. For example, the steam supply member 30i may be connected to a section extending from a second end of the first gas processing module 11i toward the upstream side into which the gas is introduced by ½ of an entire length of the first gas processing module 11i. In one or more examples, the steam supply member 30i may be connected to a section extending from the second end of the first gas processing module 11i toward the upstream side by ¼ of the entire length of the first gas processing module 11i. In one or more examples, the steam supply member 30i may be connected to a section extending from the second end of the first gas processing module 11i toward the upstream side by ⅛ of the entire length of the first gas processing module 11i. Accordingly, the aqueous vapor supplied by the steam supply member 30i may flow into a first end of the second gas processing module 12i together with the gas discharged through the second end of the first gas processing module 11i.

Since the structure in which the steam supply member 30i is connected to the first gas processing module 11i is the same as or similar to that described above in FIG. 16 and FIG. 16, the repeated description thereon will not be included herein.

Since the amount of the aqueous vapor supplied by the steam supply member 30i is the same as or similar to that described above in FIG. 17, the repeated description thereon will not be included herein. In one or more examples, the same as or similar to that described above in FIG. 17, a measurement sensor may be disposed in a direction in which the unprocessed gas BG is introduced.

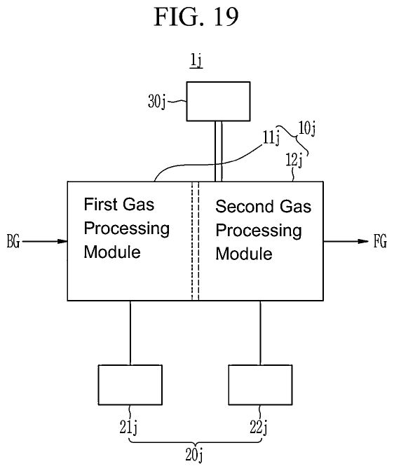

FIG. 19 is a drawing showing a gas processing apparatus 1j according to one or more embodiments.

Referring to FIG. 19, the gas processing apparatus 1j according to one or more embodiments may include a gas processing module 10j, an excitation power member 20j and a steam supply member 30j.

Upon receiving the unprocessed gas BG through a first end, the gas processing apparatus 1j may process the unprocessed gas BG, and then discharge the processed gas FG through a second end.

The gas processing module 10j may include a first gas processing module 11j and a second gas processing module 12j. Since the structure of the gas processing module 10j is the same as or similar to the gas processing module 10h described above in FIG. 17, the repeated description thereon will not be included herein.

The excitation power member 20j may include a first excitation power member 21j and a second excitation power member 22j. Since the structure of the excitation power member 20j is the same as or similar to the excitation power member 20h described above in FIG. 17, the repeated description thereon will not be included herein.

The steam supply member 30j may supply the aqueous vapor to the gas processing module 10j. The steam supply member 30j may be connected to the second gas processing module 12j. The steam supply member 30j may be of connected a first side end portion to the second gas processing module 12j. Here, the first side end portion of the second gas processing module 12j is located in the direction in which the gas is introduced, and may be referred to as an upstream side end portion of the second gas processing module 12j. For example, the steam supply member 30j may be connected to a section extending from a first end of the second gas processing module 12j toward the downstream side from which the gas is discharged by ½ of an entire length of the second gas processing module 12j. In one or more examples, the steam supply member 30j may be connected to a section extending from the first end of the second gas processing module 12j toward the downstream side by ¼ of the entire length of the second gas processing module 12j. In one or more examples, the steam supply member 30j may be connected to a section extending from the first end of the second gas processing module 12j toward the downstream side by ⅛ of the entire length of the second gas processing module 12j. Accordingly, the aqueous vapor supplied by the steam supply member 30j may generate the hydroxyl group by being decomposed by plasma within the second gas processing module 12j.

Since the structure in which the steam supply member 30j is connected to the second gas processing module 12j is the same as or similar to that described above in FIG. 16 and FIG. 16, the repeated description thereon will not be included herein.

Since the amount of the aqueous vapor supplied by the steam supply member 30j is the same as or similar to that described above in FIG. 17, the repeated description thereon will not be included herein. In one or more examples, the same as or similar to that described above in FIG. 17, a measurement sensor may be disposed in a direction in which the unprocessed gas BG is introduced.

While the embodiment of the present disclosure has been described in connection with what is presently considered to be practical embodiments, it is to be understood that the disclosure is not limited to the disclosed embodiments, but, on the contrary, is intended to cover various modifications and equivalent arrangements included within the spirit and scope of the appended claims.

What is claimed is:

1. A gas processing apparatus, comprising:
a gas processing component comprising a process fluid path through which gas flows; and
an excitation power member connected to the gas processing component and configured to provide electric power for plasma excitation,
wherein the gas processing component comprises:
(i) a ground electrode that is exposed to an interior wall of the process fluid path, and
(ii) an excitation electrode on an inner side of the process fluid path and spaced apart from the ground electrode,
wherein the excitation power member is electrically connected to the excitation electrode.

2. The gas processing apparatus of claim 1, wherein the excitation power member is configured to apply a voltage having a pulse waveform.

3. The gas processing apparatus of claim 2, wherein a pulse width of a pulse of the pulse waveform is greater than 0 μsec and smaller than or equal to 100 μsec.

4. The gas processing apparatus of claim 2, wherein a height of a pulse of the pulse waveform is greater than or equal to 10 kV.

5. The gas processing apparatus of claim 2, wherein the pulse waveform comprises a first pulse and a second pulse having different heights.

6. The gas processing apparatus of claim 2, wherein the pulse waveform comprises a first section and a second section having different frequencies.

7. The gas processing apparatus of claim 2, wherein the pulse waveform comprises a first section and a second section having different pulse widths.

8. The gas processing apparatus of claim 1, wherein the excitation electrode has a rod structure, and wherein the excitation electrode extends toward a length direction of the process fluid path.

9. The gas processing apparatus of claim 8, wherein the gas processing component comprises a plurality of excitation electrodes that includes the excitation electrode, and wherein each excitation electrode from the plurality of excitation electrodes is spaced apart from each other.

10. The gas processing apparatus of claim 1, wherein the ground electrode is a pipe structure, wherein the process fluid path is located inside the pipe structure.

11. The gas processing apparatus of claim 1, wherein the excitation electrode has a rod structure, and wherein the excitation electrode is inclined with respect to a length direction of the process fluid path.

12. The gas processing apparatus of claim 11, wherein the gas processing component comprises a plurality of excitation electrodes that includes the excitation electrode, and wherein each excitation electrode from the plurality of excitation electrodes is spaced apart from each other.

13. The gas processing apparatus of claim 1, further comprising a steam supply member configured to supply aqueous vapor to the gas processing component.

14. The gas processing apparatus of claim 1, wherein the gas processing component is a first gas processing component, and wherein the gas processing apparatus further comprises:
a second gas processing component coupled in series with the first gas processing component.

15. The gas processing apparatus of claim 14, wherein the excitation power member is a first excitation power member connected to the first gas processing component, and wherein the gas processing apparatus further comprises:
a second excitation power member connected to the second gas processing component.

16. A gas processing apparatus, comprising:
a first gas processing component comprising (i) a ground electrode that is exposed to an interior wall of a process fluid path through which gas flows, and (ii) an excitation electrode on an inner side of the process fluid path;
an first excitation power member connected to the first gas processing component and configured to provide electric power for plasma excitation;
a second gas processing component coupled in series with the first gas processing component, the second gas processing component comprising (i) a ground electrode that is exposed to an interior wall of a process fluid path through which gas flows, and (ii) an excitation electrode on an inner side of the process fluid path;
a second excitation power member connected to the second gas processing component and configured to provide electric power for plasma excitation; and
a steam supply member configured to supply aqueous vapor to one of the first gas processing component and the second gas component.

17. The gas processing apparatus of claim 16, wherein the steam supply member is connected to a region of the gas processing apparatus in which the first gas processing component and the second gas processing component are connected to each other.

18. The gas processing apparatus of claim 16, wherein the steam supply member is connected to the first gas processing component.

19. The gas processing apparatus of claim 16, wherein the steam supply member is connected to the second gas processing component.

20. A gas processing apparatus, comprising:
a first gas processing component comprising (i) a ground electrode that is exposed to an interior wall of a process fluid path through which gas flows, and (ii) an excitation electrode disposed on an inner side of the process fluid path;
an first excitation power member connected to the first gas processing component and configured to provide electric power for plasma excitation;
a second gas processing component coupled in series with the first gas processing component, the second gas processing component comprising (i) a ground electrode that is exposed to an interior wall of a process fluid path through which gas flows, and (ii) an excitation electrode disposed on an inner side of the process fluid path;
a second excitation power member connected to the second gas processing component and configured to provide electric power for plasma excitation; and
a steam supply member configured to supply aqueous vapor to one of the first gas processing component and the second gas component,
wherein the electric power supplied by the second excitation power member is greater than the electric power supplied by the first excitation power member.
